(19) United States
(12) Patent Application Publication
(10) Pub. No.: US 2010/0244960 A1
(43) Pub. Date: Sep. 30, 2010

(54) DIFFERENTIAL AMPLIFIER CIRCUIT

(75) Inventors: Seisuke TAKITANI, Tokyo (JP); Kanji OISHI, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 12/749,366

(22) Filed: Mar. 29, 2010

(30) Foreign Application Priority Data
Mar. 30, 2009 (JP) 2009-083564

(51) Int. Cl. H03F 3/45

(52) U.S. Cl. 330/253

(57) ABSTRACT

A differential amplifier circuit includes a plurality of differential-pair transistors, a plurality of current addition transistors, a latch, and a control transistor. The differential-pair transistors have gate electrodes that receive differential input signals respectively. Different potentials of the differential input signals represent a piece of information. The current addition transistors are connected in parallel to the differential-pair transistors, respectively. The latch has differential outputs corresponding to the differential input signals respectively and related to the amplified data. The control transistor receives an activation initiation signal. The current addition transistors are transitioned into electrically conductive state either in a period of time from initiation of amplification operation of the differential amplifier circuit by transitioning the control transistor into an electrically conductive state to increasing a differential voltage to cause inversion of one of the differential outputs of the latch, or at the same time when the amplification operation is initiated.

### BACKGROUND OF THE INVENTION

1. Field of the Invention

The present invention relates to a differential amplifier circuit which is mounted on a semiconductor device.

Priority is claimed on Japanese Patent Application No. 2009-083564, filed Mar. 30, 2009, the content of which is incorporated herein by reference.

2. Description of the Related Art

In a semiconductor device which is represented by a DRAM (Dynamic Random Access Memory) or the like, in order to realize a high-speed operation, a minute voltage from a memory cell onto a bit line is amplified to a CMOS level by a differential amplifier circuit, such as a sense amplifier or a data amplifier, and data is finally read out outside of the apparatus.

### SUMMARY

In one embodiment, a differential amplifier circuit may include, but is not limited to, a plurality of differential-pair transistors, a plurality of current addition transistors, a latch, and a control transistor. The plurality of differential-pair transistors has gate electrodes that receive differential input signals respectively. Different potentials of the differential input signals represent a piece of information. The plurality of current addition transistors are connected in parallel to the plurality of differential-pair transistors, respectively. The latch is connected to the plurality of differential-pair transistors. The latch is connected to the plurality of current addition transistors. The latch holds amplified data which have been generated by amplifying the plurality of differential input signals. The latch has a plurality of differential outputs. The plurality of differential outputs is related to the amplified data. The plurality of differential outputs corresponds to the differential input signals respectively. The control transistor is connected to the plurality of differential-pair transistors. The control transistor is connected to the plurality of current addition transistors. The control transistor receives an activation initiation signal. The plurality of current addition transistors are transitioned into electrically conductive state either in a period of time from initiation of amplification operation of the differential amplifier circuit by transitioning the control transistor into an electrically conductive state to increasing a differential voltage to cause inversion of one of the plurality of differential outputs of the latch, or at the same time when the amplification operation is initiated.

In another embodiment, a differential amplifier circuit may include, but is not limited to, a differential input circuit; and a latch. The differential input circuit may include, but is not limited to, first, second, third and fourth transistors and a control transistor. The first and second transistors have gate electrodes that receive differential input signals respectively. Different potentials of the differential input signals represent a piece of information. The control transistor is connected in series to the first differential-pair transistor. The control transistor is connected in series to the second differential-pair transistor. The control transistor receives an activation initiation signal. The third and fourth transistors are connected in parallel to the first and second transistors. The latch may include, but is not limited to, first and second inverters having gates and outputs which are cross-coupled to each other. The first and second inverters have a plurality of differential outputs having a differential voltage greater than a differential voltage of the plurality of differential input signals, related to the plurality of differential input signals. The first and second inverters output the plurality of differential outputs after operations of the first and second inverters. The first and second inverters have sources which are connected in series to a plurality of outputs of the differential input circuit. The plurality of outputs of the differential input circuit corresponds to the plurality of differential input signals. The third and fourth transistors are transitioned into electrically conductive state either in a period of time from initiation of amplification operation of the first and second transistors by transitioning the control transistor into an electrically conductive state to increasing a differential voltage to cause inversion of one of the plurality of differential outputs of the latch, or at the same time when the amplification operation is initiated.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a circuit diagram of a differential amplifier circuit according to an embodiment of the invention;

FIGS. 2A and 2B are timing charts showing amplification operations of the differential amplifier circuit in FIG. 1;

FIG. 3 is a diagram illustrating waveforms in which the differential output signals of the known differential amplifier circuit and the differential amplifier circuit of an embodiment are plotted on the same graph;

FIG. 4 is a circuit diagram of a differential amplifier circuit according to another embodiment of the invention;

FIGS. 5A and 5B are a timing chart showing an amplification operation of the differential amplifier circuit of FIG. 4;

FIG. 6 is a circuit diagram of a differential amplifier circuit according to yet another embodiment of the invention;

FIGS. 7A and 7B are timing charts showing amplification operations of the differential amplifier circuit in FIG. 6;

FIG. 8 is a circuit diagram of a differential amplifier circuit of the related art; and

FIGS. 9A and 9B are timing charts showing an amplification operation of the differential amplifier circuit of FIG. 8.

### DETAILED DESCRIPTION OF THE PREFERRED EMBODIMENTS

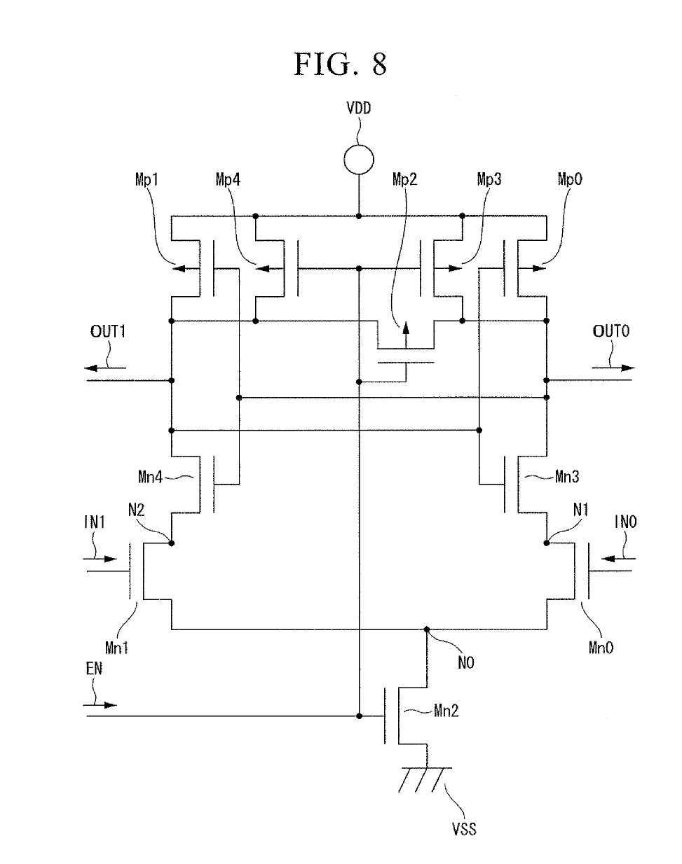

As shown in FIG. 8, a differential amplifier circuit of the related art includes a latch which has two cross-coupled inverters between a high-potential power source (VDD) and a low-potential power source (VSS), differential-pair transistors (Mn0 and Mn1) to which differential input signals are input, and a control transistor (Mn2).

In FIG. 8, in the differential amplifier circuit, after a differential voltage is generated between the differential input signals (IN0 and IN1), the control transistor is turned on to cause a difference in the current flowing in the differential-pair transistors and to cause a difference in the voltage level between differential outputs (Out0 and Out1) in accordance with the differential input signals. The latch amplifies one of the differential outputs to the voltage level of the high-potential power source and the other differential output to the voltage level of the low-potential power source, and latches (holds) the logic levels of the differential outputs during a period in which the control transistor is turned on.

The above-described differential amplifier circuit and the improved differential amplifier circuit are disclosed in JP-A-10-3791, JP-A-2007-116722 (U.S. Pat. No. 5,502,680), JP-A-2003-323800, U.S. Pat. No. 5,508,644, and U.S. Pat. No. 5,192,878.

The differential amplifier circuits described in those publications have reduced amplification speeds. The reduction in amplification speed can be due to the reduction in voltage of the high-potential power source or reduction in voltage of the differential input signals.

The reason why the amplification speed is delayed is that transistors constituting the latch, the differential-pair transistors, and the control transistor are connected to each other in series between the output node of the differential amplifier and the low-potential power source, so there is lowered the drive ability of the transistors constituting the latch and the differential-pair transistors involved in the amplification operation. In addition, the drive ability of the transistors becomes lowered due to a threshold voltage Vt which is erroneously increased for each of the transistors constituting the latch and the differential-pair transistors involved in the amplification operation in manufacturing processes of a semiconductor device. Such erroneous increase in the threshold voltage Vt also delays the amplification speed. Accordingly, the differential signals that are input to the differential-pair transistors are at low voltage, so the differential amplifier circuit can no longer perform the amplification operations.

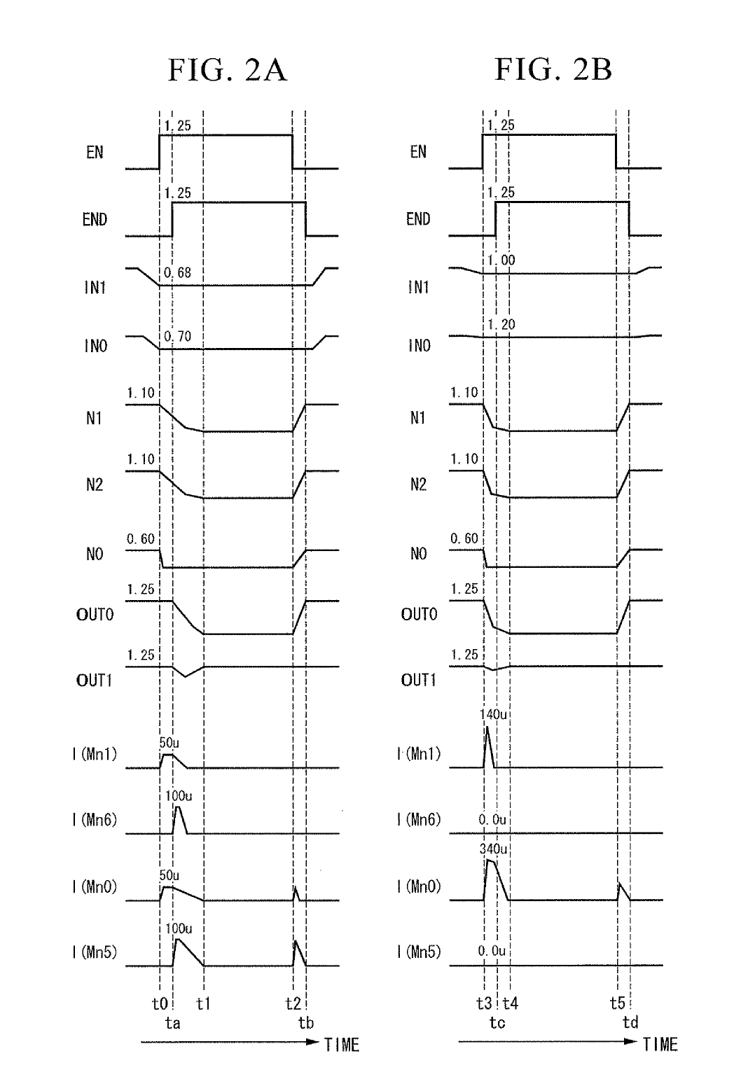

The differential amplifier circuit shown in FIG. 2 of JP-A-10-3791 is the differential amplifier circuit which is described in the background art, and the above-described problem is not solved.

In the differential amplifier circuit shown in FIG. 2 of JP-A-2007-116722 (U.S. Pat. No. 5,502,680), the control transistor, the differential-pair transistors, and the latch are connected in these orders between the high-potential power source (VDD) and the low-potential power source (VSS), and bypass transistors are provided between the control transistor and the latch to correspond to the differential-pair transistors. The bypass transistors are turned on later than the signal input to the gate terminal of the control transistor.

However, the bypass transistors are transistors are provided to set the H-level node of the latch at the voltage level of the high-potential power source. In other words, the bypass transistors are transistors for realizing the CMOS output voltage. Before the bypass transistors are turned on, the amplification operation is already completed. Accordingly, such differential amplifier circuits are not substantially improved in the amplification speed.

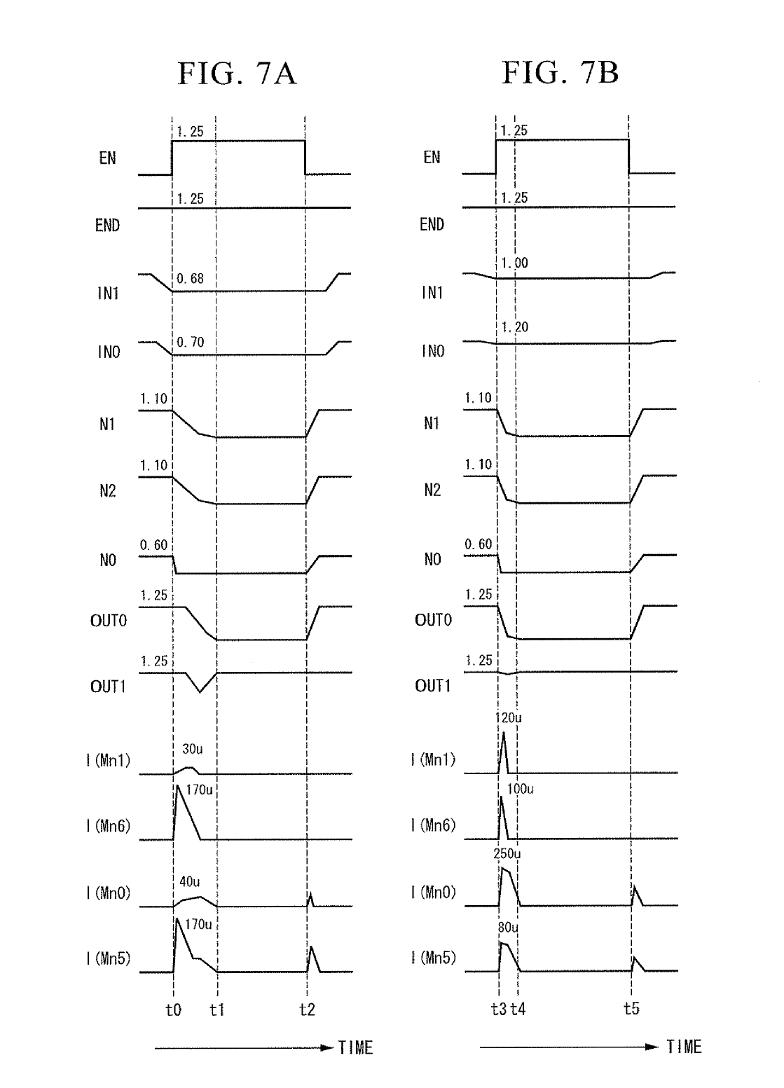

The differential amplifier circuit shown in FIG. 7 of JP-A-2003-323800 is configured such that a transistor is connected in parallel to each of the differential-pair transistors in the differential amplifier circuit described in the background art. Then, the parallel-connected transistor is turned on later than the signal input to the gate terminal of the control transistor. However, the parallel-connected transistor is provided to maintain the latch state of the latch when the gate voltage of each of the differential-pair transistors is inactivated or initialized. Before the parallel-connected transistor is turned on, the amplification operation has already been completed. Accordingly, the differential amplifier circuit is not substantially improved in the amplification speed.

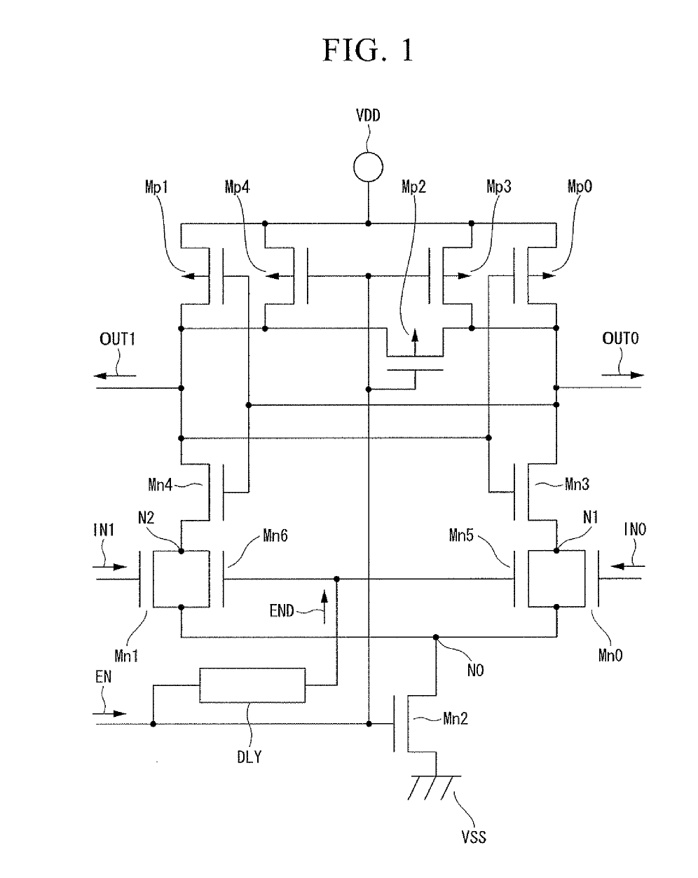

The differential amplifier circuit shown in FIG. 1 of U.S. Pat. No. 5,508,644 is configured such that a transistor is connected in parallel to the control transistor in the differential amplifier circuit described in the background art, Then, the parallel-connected transistor has a gate terminal fixedly connected to the high-potential power source. The parallel-connected transistor causes a micro current to constantly flow in the differential amplifier circuit such that the differential amplifier circuit is in the operation state. It is necessary to reduce the driving ability of the transistor so as to suppress the micro current through it, there is a further increase in the resistance value of the transistors constituting the latch, the differential-pair transistors, and the control transistor which are connected in series between the output node of the differential amplifier and the low-potential power source. The amplification speed can not be increased. For this reason, reduction in voltage of the differential input signals makes it impossible to solve the problem with the amplification speed delay. That is, such an improved differential amplifier circuit is not substantially improved in the amplification speed.

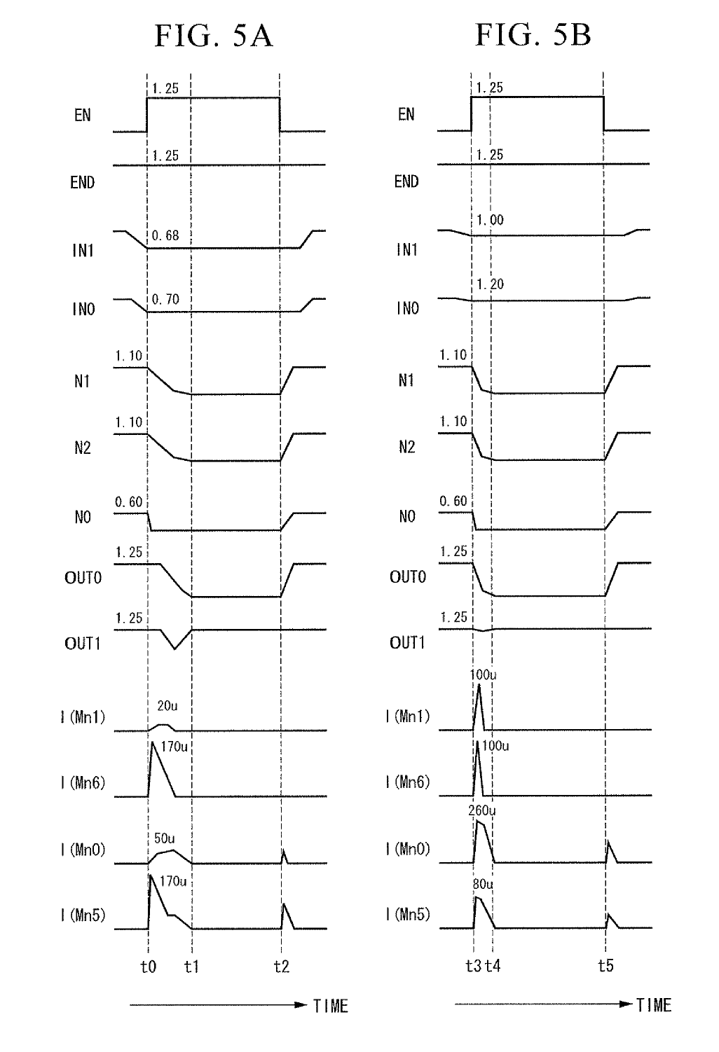

The differential amplifier circuit shown in FIG. 5 of U.S. Pat. No. 5,192,878 is a differential amplifier circuit in which an additional transistor is further provided between the output node of the differential amplifier of the latch and the low-potential power source in the differential amplifier circuit described in the background art. Then, the gate terminal of the additional transistor is controlled by inverters 31 and 32 to which the output node of the differential amplifier is input. However, the additional transistor is not involved in the amplification operation until the voltage level of one of the differential outputs becomes the voltage level lower than the logical threshold value of the inverter, so the problem regarding improvement in the amplification speed can not be solved.

As described above, in the differential amplifier circuit of the related art, with reduction in voltage of the high-potential power source or reduction in voltage of the differential input signals, it is not impossible to solve the problem of the amplification speed being delayed, and the problem of the amplification speed being delayed when the threshold voltage Vt of each of the transistors constituting the latch and the differential-pair transistors involved in the amplification operation is significantly deviated in the manufacturing process of the semiconductor device.

The invention will be now described herein with reference to illustrative embodiments. Those skilled in the art will recognize that many alternative embodiments can be accomplished using the teaching of the present invention and that the invention is not limited to the embodiments illustrated for explanatory purpose.

In one embodiment, a differential amplifier circuit may include, but is not limited to, a plurality of differential-pair transistors, a plurality of current addition transistors, a latch, and a control transistor. The plurality of differential-pair transistors has gate electrodes that receive differential input signals respectively. Different potentials of the differential input signals represent a piece of information. The plurality of current addition transistors are connected in parallel to the plurality of differential-pair transistors, respectively. The latch is connected to the plurality of differential-pair transistors. The latch is connected to the plurality of current addition transistors. The latch holds amplified data which have been generated by amplifying the plurality of differential input signals. The latch has a plurality of differential outputs. The plurality of differential outputs is related to the amplified data. The plurality of differential outputs corresponds to the differential input signals respectively. The control transistor is connected to the plurality of differential-pair transistors. The control transistor is connected to the plurality of current addition transistors. The control transistor receives an activation initiation signal. The plurality of current addition transistors are transitioned into electrically conductive state either in a period of time from initiation of amplification operation of the differential amplifier circuit by transitioning the control transistor into an electrically conductive state to increasing a differential voltage to cause inversion of one of the plurality of differential outputs of the latch, or at the same time when the amplification operation is initiated.

In some cases, each of the gates of the plurality of current addition transistors may be coupled to a delayed signal that is generated by delaying the activation initiation signal with a predetermined time, so as to add a predetermined current to respective currents flowing through the plurality of differential-pair transistors.

In some cases, each of the gates of the plurality of current addition transistors may be coupled to a predetermined voltage, the predetermined voltage is either one of a higher power voltage and a lower power voltage or a potential between the higher power voltage and the lower power voltage.

In some cases, the gates of the plurality of current addition transistors may be coupled to nodes of the plurality of differential outputs having the same phase as the plurality of differential input signals respectively.

In some cases, the plurality of differential-pair transistors and the plurality of current addition transistors may be coupled between one of a higher power voltage and a lower power voltage and other of the higher power voltage and the lower power voltage, the other being applied to the latch.

In some cases, the latch may include, but is not limited to, first and second inverters have gates and outputs which are cross-coupled to each other. The plurality of differential-pair transistors and the plurality of current addition transistors are connected in parallel to each other. Each of the plurality of differential-pair transistors is connected in series between a higher power voltage and a lower power voltage. Each of the plurality of current addition transistors is connected between the higher power voltage and the lower power voltage.

In some cases, the plurality of differential-pair transistors and the plurality of current addition transistors may be connected in parallel to each other. The plurality of differential-pair transistors and the plurality of current addition transistors, the first and second inverters and the control transistor may be connected in series between the higher power voltage and the lower power voltage.

In some cases, the plurality of differential-pair transistors and the plurality of current addition transistors may be connected in parallel to each other. The plurality of differential-pair transistors and the plurality of current addition transistors, the first and second inverters and the control transistor may be connected in series between the higher power voltage and the lower power voltage.

In some cases, the plurality of differential-pair transistors and the plurality of current addition transistors may be field effect transistors of the same conductivity type.

In some cases, the control transistor may be a field effect transistor of the same conductivity type as the plurality of differential-pair transistors and the plurality of current addition transistors.

In some cases, the first inverter may be a transistor of a first conductivity type. The second inverter may be a transistor of a second conductivity type. One of the transistors of the first conductivity type and the second conductivity type is the same conductivity type as the plurality of differential-pair transistors and the plurality of current addition transistors.

In another embodiment, a differential amplifier circuit may include, but is not limited to, a differential input circuit; and a latch. The differential input circuit may include, but is not limited to, first, second, third and fourth transistors and a control transistor. The first and second transistors have gate electrodes that receive differential input signals respectively. Different potentials of the differential input signals represent a piece of information. The control transistor is connected in series to the first differential-pair transistor. The control transistor is connected in series to the second differential-pair transistor. The control transistor receives an activation initiation signal. The third and fourth transistors are connected in parallel to the first and second transistors. The latch may include, but is not limited to, first and second inverters having gates and outputs which are cross-coupled to each other. The first and second inverters have a plurality of differential outputs having a differential voltage greater than a differential voltage of the plurality of differential input signals, related to the plurality of differential input signals. The first and second inverters output the plurality of differential outputs after operations of the first and second inverters. The first and second inverters have sources which are connected in series to a plurality of outputs of the differential input circuit. The plurality of outputs of the differential input circuit corresponds to the plurality of differential input signals. The third and fourth transistors are transitioned into electrically conductive state either in a period of time from initiation of amplification operation of the first and second transistors by transitioning the control transistor into an electrically conductive state to increasing a differential voltage to cause inversion of one of the plurality of differential outputs of the latch, or at the same time when the amplification operation is initiated.

In some cases, each of the gates of the third and fourth transistors is coupled to a delayed signal that is generated by delaying the activation initiation signal with a predetermined time, so as to add a predetermined current to respective currents flowing through the first and second transistors.

In some cases, each of the gates of the third and fourth transistors is coupled to a predetermined voltage. The predetermined voltage is either one of a higher power voltage and a lower power voltage or a potential between the higher power voltage and the lower power voltage.

In some cases, the gates of the third and fourth transistors may be coupled to nodes of the plurality of differential outputs having the same phase as the plurality of differential input signals respectively.

In some cases, the gates of the third and fourth transistors may be connected to nodes of the plurality of differential outputs controlled at a predetermined high potential before the first and second transistors perform amplification operations.

In some cases, the first, second, third and fourth transistors may be field effect transistors of the same conductivity type.

In some cases, the control transistor may be a field effect transistor of the same conductivity type as the first, second, third and fourth transistors.

In some cases, the first inverter may be a transistor of a first conductivity type. The second inverter may be a transistor of a second conductivity type. One of the transistors of the first conductivity type and the second conductivity type is the same conductivity type as the first, second, third and fourth transistors.

In some cases, the first inverter is a transistor of a first conductivity type, the second inverter is a transistor of a second conductivity type. One of the transistors of the first conductivity type and the second conductivity type is the same conductivity type as the first, second, third and fourth transistors.

A representative example of the technical idea for solving the above-described problem will be described below. Needless to say, the scope of the invention is not limited to the technical idea but is defined by the appended claims.

For example, a case is considered where the differential output signals of the differential amplifier circuit are OUTT and OUTB, and the difference between the voltage levels OUTT and OUTB is amplified by an NMOS transistor MnT and an NMOS transistor MnB which are cross-coupled in the latch. The NMOS transistors MnT and MnB are connected to each other in series through NMOS transistors MnBT (having a differential input signal INT as an input) and MnBB (having a differential input signal INB as an input) as differential-pair transistors and common connection points JT and JB, and the source terminals of the differential-pair transistors are commonly connected to the control transistor. When the condition “voltage level of differential input signal INT>voltage level of differential input signal INB” is satisfied, amplification is carried out such that the condition “voltage level of differential output signal OUTT<voltage level of differential output signal OUTB” is satisfied.

However, when the voltage levels of the differential input signals are low, for example, to be close to the threshold voltage level of each of the differential-pair transistors, voltage drop of the connection point JT or JB is remarkably moderate, as compared with a case where the differential input signals are high, and as a result, the transistors of the latch carry out amplification moderately.

Accordingly, a differential amplifier circuit according to the invention is to meet demands for a high-speed operation even when the voltage levels of the differential input signals are lowered close to the threshold voltage level.

That is, the differential amplifier circuit of the invention is to improve precision and an operation point of the differential amplifier circuit, and the technical idea of the invention resides in that a current addition transistor is connected in parallel to the differential-pair transistors, and an addition current, referred to as “base-up current”, in the amplification operation is added with respect to the differential-pair transistors.

Hereinafter, embodiments of the invention will be described in detail with reference to the accompanying drawings.

### First Embodiment

FIG. 1 is a circuit diagram of a differential amplifier circuit according to an embodiment of the invention.

In FIG. 1, reference numeral VDD denotes a voltage level of a high-potential power source, reference numeral VSS denotes a voltage level of a low-potential power source, reference numeral EN denotes an activation initiation signal (amplification initiation signal EN) of the differential amplifier circuit, reference numerals IN0 and IN1 denote differential (complementary) input signals, and reference numerals OUT0 and OUT1 denote differential output signals. As shown in FIG. 1, the differential amplifier circuit according to the embodiment of the invention includes PMOS transistors Mp0 to Mp4, NMOS transistors Mn0 to Mn6, and a delay DLY.

The NMOS transistor Mn0 and the NMOS transistor Mn1 are differential-pair transistors having gate terminals to which the differential input signal IN0 and the differential input signal IN1 are input. The NMOS transistor Mn2 is a control transistor having a gate terminal to which the amplification initiation signal EL (activation initiation signal) which is changed from the voltage level of the low-potential power source (hereinafter, referred to as L level) to the voltage level of the high-potential power source (hereinafter, referred to as H level) at the time of the start of amplification. Although in this embodiment, the differential-pair transistors (NMOS transistor Mn0 and NMOS transistor Mn1) are commonly connected to the drain terminal of the control transistor (NMOS transistor Mn2), a control transistor may be provided for each of the differential-pair transistors.

The PMOS transistor Mp0, the PMOS transistor Mp1, the NMOS transistor Mn3, and the NMOS transistor Mn4 form a latch which holds data of differential input signals IN0 which is input into the differential-pair transistor (NMOS transistor Mn0), and data of differential input signals IN1 which is input into the differential-pair transistor (NMOS transistor Mn1). The latch includes first and second invertors cross-coupled to each other. The first inverter includes the PMOS transistor Mp0 and the NMOS transistor Mn3. The second inverter includes the PMOS transistor Mp1 and the NMOS transistor Mn4. The differential output signals OUT0 and OUT1 are output from the first and second inverters, respectively. The differential output signals OUT0 and OUT1 are the differential outputs from the differential amplifier circuit.

In the first and second inverters, the PMOS transistor Mp3 and the PMOS transistor Mp4 which are respectively connected in parallel to the PMOS transistors Mp0 and Mp1 are precharge transistors which are turned on when the amplification initiation signal EN is at L level to pull up the differential output signals OUT0 and OUT1 to the voltage level VDD of the high-potential power source. The PMOS transistor Mp2 which is provided between the differential outputs sets the differential output signals OUT0 and OUT1 at the same level when the amplification initiation signal EN is at L level, and suppresses occurrence of a voltage difference in the differential outputs immediately before the start of amplification.

The NMOS transistor Mn5 and the NMOS transistor Mn6 which are respectively connected in parallel to the differential-pair transistors (NMOS transistor Mn0 and NMOS transistor Mn1) are current addition transistors which add the base-up current with respect to the differential-pair transistors at the time of amplification. A delay signal END which is obtained by delaying the amplification initiation signal EN by the delay DLY is input to the gate terminals of the NMOS transistor Mn5 and the NMOS transistor Mn6.

In the drawing, the differential amplifier circuit of this embodiment includes transistors having the following transistor constant, that is, W (channel width)/L (channel length). The NMOS transistors Mn3 and Mn4 constituting a flip-flop of the latch have W/L=3 μm/0.1 μm, the NMOS transistors Mn0 and Mn1 constituting the differential-pair transistors have W/L=2 μm/0.1 μm, the NMOS transistors Mn5 and Mn6 constituting the addition current transistors have W/L=0.5 μm/0.1 μm, and the NMOS transistor Mn2 constituting the control transistor has W/L=5 μm/0.1 μm. The PMOS transistors Mp0 to Mp4 have W/L=2.5 μm/0.1 μm.

The relationship between the NMOS transistors constituting the differential amplifier circuit is as follows:

(1) The relationship between the differential-pair transistors and the current addition transistors, that is, the relationship between the drain current of the NMOS transistor Mn0 and the drain current of the NMOS transistor Mn5 (or the drain current of the NMOS transistor Mn1 and the drain current of the NMOS transistor Mn6) is as follows. When no base-up current flows, the voltage drop speed (discharge speed) at a node N1 (the common connection point of Mn0 and Mn3) is in proportion to the drain current of the NMOS transistor Mn0. If the gate voltage of the NMOS transistor Mn0 is VG and the threshold voltage is Vt, the drain current ID is in proportion to the square of (VG−Vt), and thus the discharge speed is in proportion to the square of (VG−Vt). Meanwhile, if the voltage level of the differential input signal is at the gate voltage (represented by VG′) close to the threshold voltage Vt, the discharge speed is in proportion to the square of (VG′−Vt).

If the discharge speed when the NMOS transistor Mn5 having a channel width W5 in which the base-up current flows is added to the NMOS transistor Mn0 having a channel width WO is η times higher than the discharge speed when the gate voltage before addition is VG, the gate voltage (represented by VG″) of the NMOS transistor Mn5 is calculated by (W5×(VG″−Vt)²+W0×(VG′−Vt)²):W0×(VG−Vt)²η:1. Thus, the drain current of the NMOS transistor Mn5 is determined by the calculated gate voltage VG″. That is, the relationship between the drain current flowing in the differential input transistor (NMOS transistor Mn0) and the drain current (base-up current) flowing in the current addition transistor (NMOS transistor Mn5) is uniquely determined by a desired speed ratio η set in advance with the power supply voltage and the voltage levels of the differential input signals near the threshold voltage as known values.

For example, in this embodiment, if the high-potential power supply voltage level of the differential amplifier circuit is at 1.25 V, the voltage levels of the differential input signals is at 0.68 V and 0.70 V, the channel length L of the NMOS transistor is 0.1 μm, the channel width WO of the NMOS transistor Mn0 is 2 μm, and the channel width W5 of the NMOS transistor Mn5 is 0.5 μm, the discharge speed can be increased about two times, as compared with the discharge speed with only the NMOS transistor Mn0.

(2) The relationship between the differential-pair transistors, the current addition transistors, and the control transistor, that is, the relationship between the drain current of the NMOS transistors Mn0 and Mn5 (or the NMOS transistors Mn1 and Mn6) and the drain current of the NMOS transistor Mn2 is as follows. A source voltage is preferably close to the voltage level of the low-potential power source such that the NMOS transistor Mn2 does not become a bottleneck during the amplification operation, that is, the gate-source voltage is sufficient when the NMOS transistors Mn0 and Mn5 draw current from the output node of the differential amplifier of the latch through the node N1.

Accordingly, the magnitude of the drain current of Mn2 should be an extent such that a current flowing in Mn0 and Mn5 can be sufficiently absorbed. For example, in this embodiment, when the channel length L of the NMOS transistor is 0.1 μm and the channel widths W of the NMOS transistors Mn0 and Mn5 are 2 μm and 0.5 μm, the channel width W of Mn2 is about 5 μm.

FIGS. 2A and 2B are timing charts showing amplification operations of the differential amplifier circuit in FIG. 1.

FIGS. 2A and 2B show current waveforms of main nodes of the differential amplifier circuit which operates with a power supply voltage 1.25 V and current waveforms in the differential-pair transistors and the current addition transistors. FIG. 2A shows waveforms when the voltage levels of the differential input signals are at 0.70 V and 0.68 V close to the threshold voltage (about 0.6 V). FIG. 2B shows waveforms when the voltage levels of the differential input signals are at 1.2 V and 1.0 V close to the power supply voltage. Hereinafter, the operation of the differential amplifier circuit will be described with reference to FIG. 2A. FIG. 2B will be described in comparison of the effects with the related art.

First, before the amplification start time t0, the voltage levels of all the nodes are in the initial state. The PMOS transistors Mp2 to Mp4 are turned on to precharge the differential output signals OUT0 and OUT1 to 1.25 V.

At the time t0, the NMOS transistors Mn0 and Mn1 (differential-pair transistors) are not turned on, and the amplification operation does not start. If the amplification initiation signal EN is at H level, the NMOS transistor Mn2 (control transistor) is turned on, such that the node N0 is discharged, and the voltage level is substantially changed to 0 V. Thus, the gate-source voltages of the NMOS transistors Mn0 and Mn1 (differential-pair transistors) are respectively 0.7 V and 0.68 V and exceed the threshold voltage, the NMOS transistors Mn0 and Mn1 are turned on and respectively start to discharge the nodes N1 and N2. At this time, the relationship between the drain current I(Mn0) and I(Mn1) flowing in the NMOS transistors Mn0 and Mn1 is I(Mn0)>I(Mn1) since the difference in the gate voltage between the differential-pair transistors is 20 mV. Thus, the node N1 is discharged at a discharge speed higher than the node N2. In the current waveforms of the drawing, the gate-source voltage is substantially identical, so it is shown that the peak current is about 50 μA and there is no difference between both nodes, but the current relationship is as described above.

Each of the NMOS transistors Mn3 and Mn4 constituting the flip-flop in the latch is turned on if the source voltage level drops, and the gate-source voltage exceeds the threshold voltage level, and starts to drop the voltage levels of the differential outputs. From the above-described current relationship, the node N1 undergoes voltage drop earlier than the node N2, so the NMOS transistor Mn3 is turned on earlier than the NMOS transistor Mn4. Subsequently, the NMOS transistor Mn4 is also turned on, and the drain current flows in both transistors in a state where the gate-source voltage is close to the threshold voltage. Accordingly, a difference in the gate-source voltage and the drain-source voltage between both transistors is gradually generated, so a difference starts to be generated between the voltage levels of the differential outputs. It should be noted that both nodes (node N1 and node N2) do not reach (exceed) the threshold voltages of the PMOS transistors Mp0 and Mp1, so both nodes continue to drop from a predetermined potential.

At the time ta, the delay DLY outputs the delay signal END which is obtained by delaying the amplification initiation signal EN. Thus, the drain current I(Mn5) and I(Mn6) flow (the base-up current flows) in the NMOS transistors Mn5 and Mn6 (current addition transistors), resistance between the nodes N0 and N1 and resistance between the nodes N0 and N2 decrease, and voltage drops at the nodes N1 and N2 are accelerated. That is, a plurality of current addition transistors are in the conduction state before the differential voltage is released in a direction in which one of the differential outputs of the latch is inverted, and changes of both nodes (one node and the other node) of the differential outputs are accelerated, such that the PMOS transistor Mp1 (or Mp0) is accelerated to reach the threshold voltage.

The base-up current flows, such that in the NMOS transistors Mn3 and Mn4 of the latch, the difference in the gate-source voltage and the difference in the drain-source voltage between both transistors increase. That is, the latch further advances the amplification operation and further increases the difference in the voltage level between the differential outputs. Then, if the voltage level of the differential output signal OUT0 is lower than the high-potential power supply voltage level VDD by the absolute value of the threshold voltage of the PMOS transistor Mp1, the PMOS transistor Mp1 is turned on, and the voltage level of the differential output signal OUT1 increases to the high-potential power supply voltage level VDD. That is, the base-up current by the current addition transistors accelerates the time at which the differential direction is created in a direction in which one of the differential outputs of the latch is inverted. Meanwhile, the NMOS transistor Mn3 drops the differential output signal OUT0 to the low-potential power supply voltage level GND through the NMOS transistors Mn0, Mn5, and Mn2 (differential-pair transistors and control transistor). Thus, at the time t1, the differential amplifier circuit sets the differential output signal OUT1 at the voltage level VDD and the differential output signal OUT0 at the voltage level GND, and completes the amplification operation to the CMOS level of the differential output signal. Thereafter, at the time t2, the differential amplifier circuit continues to latch the data by the cross-coupled inverters of the latch until the amplification initiation signal EN is changed to L level. At the time t2, the differential output signals OUT0 and OUT1 and the nodes N0, N1, and N2 are reset in the initial state.

As described above, the differential amplifier circuit of this embodiment includes the differential-pair transistors (Mn0 and Mn1) having gate electrodes, to which differential input signals are input, a plurality of current addition transistors (Mn5 and Mn6) which are respectively connected in parallel to the differential-pair transistors, the latch (Mp0, Mp1, Mn3, and Mn4) which is connected to the differential-pair transistors and a plurality of current addition transistors, and holds amplified data of the differential input signals, and the control transistor (Mn2) to which the activation initiation signal (amplification initiation signal EN) is input. If the activation initiation signal is input, the differential amplifier circuit starts the amplification operation, and a plurality of current addition transistors are in the conduction state before the differential voltage is released in a direction in which one of the differential outputs of the latch is inverted, or simultaneously with the amplification operation.

According to the embodiment, the differential amplifier circuit is configured such that the transistor in which the addition current flows is connected in parallel to the differential-pair transistors to which the differential signals are input, so the differential input signals are at low voltage, and even when the current value flowing in the differential-pair transistors during the amplification operation is very small, the latch (flip-flop) operates at high speed without erroneously operating.

That is, the latch (flip-flop) starts a differential operation by the differential-pair transistors, and after the time such that a high-speed operation is ensured, the base-up current flows in the current addition transistors by the delay DLY, so an erroneous operation of the differential amplifier circuit is reduced, and the amplification operation can be performed at high speed, as compared with the related art. In the differential amplifier circuit, the threshold voltage Vth of each of the transistors in the latch involved in amplification and the differential-pair transistors is high, the differential-pair transistors decrease the flowing current, and the differential amplifier circuit is hard to operate. For this reason, the base-up current flows by the current addition transistors, such that the differential amplification operation of the latch can operate at high speed without erroneously operating.

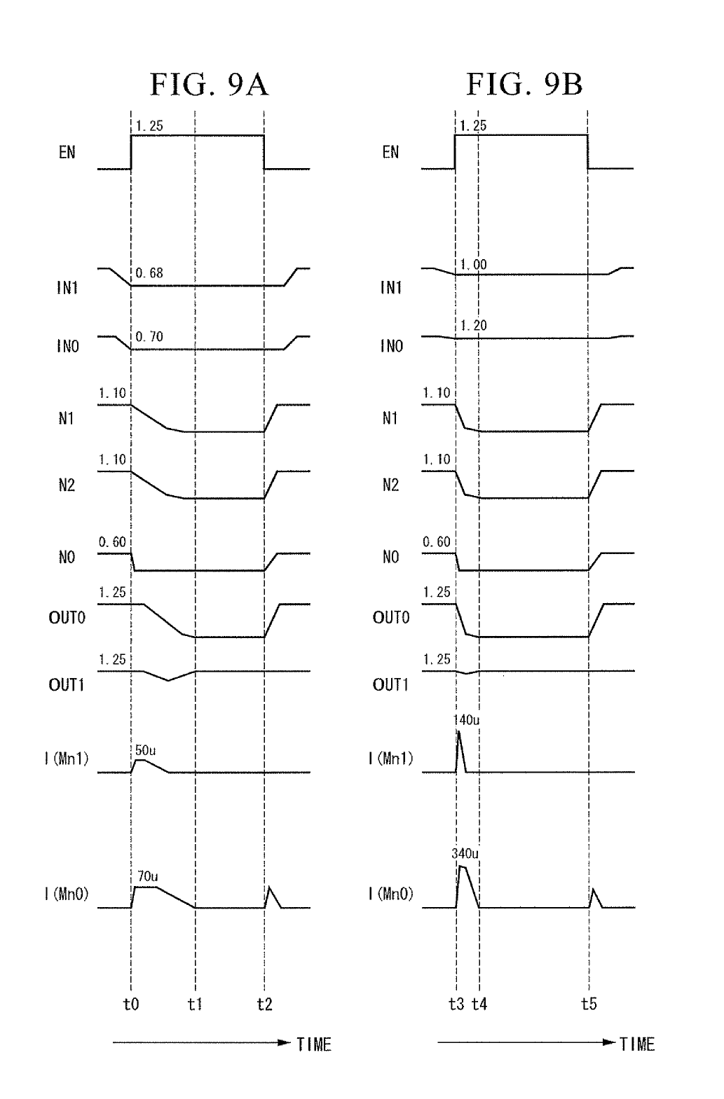

Comparison with the related art will be provided in connection with the drawing. FIG. 8 is a circuit diagram of a differential amplifier circuit of the related art. The transistors, the input signal, and the like are represented by the same reference numerals as those in FIG. 1. FIGS. 9A and 9B are timing charts showing an amplification operation of the differential amplifier circuit of FIG. 8.

The differential amplifier circuit of the related art has no current addition transistors, so in FIG. 8, the NMOS transistors Mn5 and Mn6 are not show, and in FIG. 9, I(Mn5) and I(Mn6) are not shown.

If the voltage levels of the differential input signals are 0.7 V/0.68 V close to the threshold voltage, then, comparison is done in connection with FIG. 2A and FIG. 9A. The known differential amplifier circuit uses only the NMOS transistors Mn0 and Mn1 (differential-pair transistors) to draw electric charges from the output node of the differential amplifier of the flip-flop. For this reason, the voltage drop speed at the nodes N0 and N1 are low, it takes a lot of time to perform the amplification operation, and I(Mn0) and I(Mn1) continue to flow in the meantime. It is also found that the change in voltage of the differential output signal OUT0/OUT1 is slow. In contrast, in the differential amplifier circuit of this embodiment, it is found that the base-up current makes the voltage drop speed at the nodes N0 and N1 high, and makes rapid the change in voltage of the differential output signal OUT0/OUT1.

FIG. 2B and FIG. 9B show waveforms when the voltage levels of the differential input signals are at 1.2 V and 1.0 V close to the power supply voltage VDD. It should be noted that there is little difference between the waveforms. This is because, in the differential amplifier circuit of this embodiment, at the time (corresponding to the time tc) at which the base-up current flows, the amplification operation is substantially completed. That is, the reason is that the voltage level of the differential input signal is high, so when the delay signal END is input to the NMOS transistors Mn5 and Mn6, and the base-up current flows, the voltage levels at the node N0 and the node N1 undergo voltage drop, and there is no difference in voltage between the source and the drain of the NMOS transistors Mn5 and Mn6.

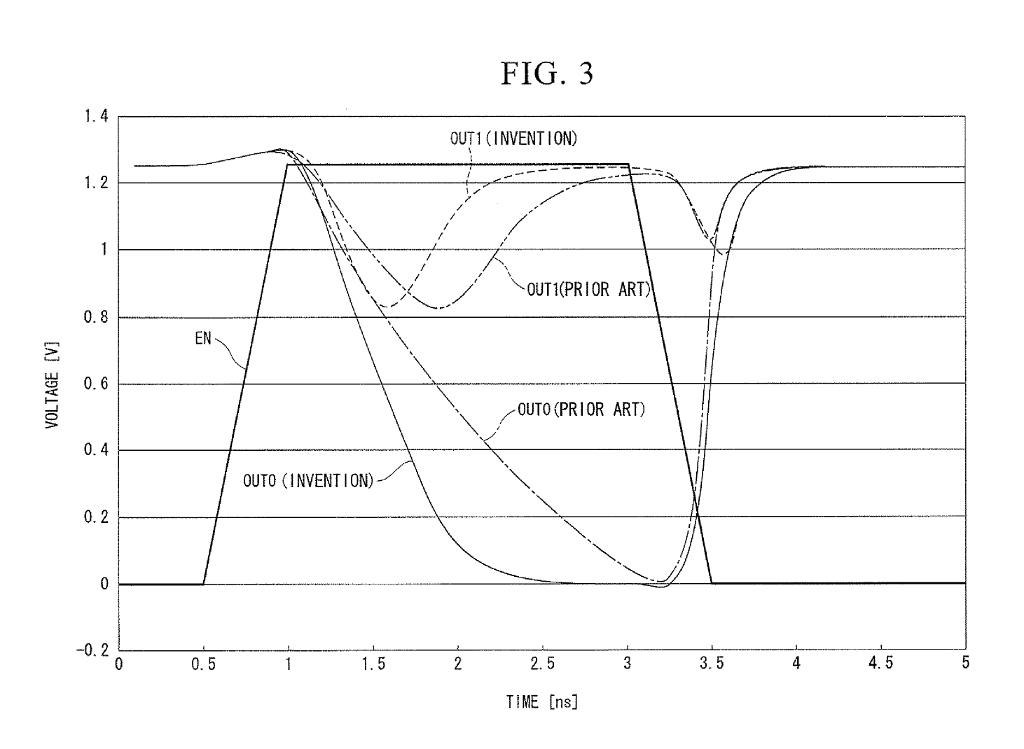

FIG. 3 is a waveform chart in which the differential output signals of the known differential amplifier circuit and the differential amplifier circuit of this embodiment are plotted on the same graph. In this waveform chart, similarly to FIGS. 2A and 9A, the conditions are that the voltage level VDD of the high-potential power source is at 1.25 V, and the differential input signals IN0 and IN1 are 0.7 V and 0.68 V. Referring to the waveform chart, in the differential amplifier circuit of this embodiment, it is found that, even when the voltage levels of the differential input signals are lowered close to the threshold voltage, the difference in voltage between the differential output signals OUT0 and OUT1 is amplified fast with no erroneous operation, as compared with the related art.

### Second Embodiment

Next, another embodiment of the invention will be described.

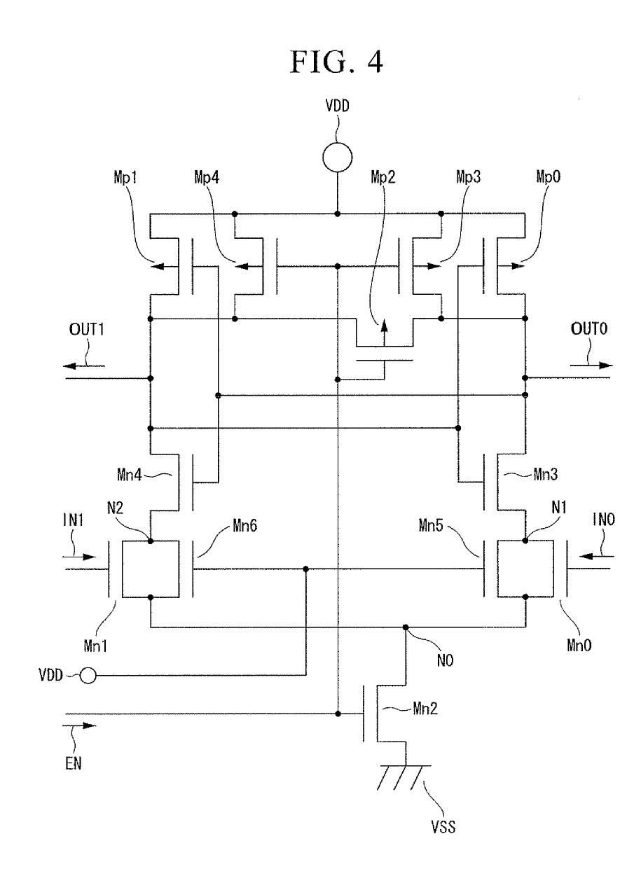

FIG. 4 is a circuit diagram of a differential amplifier circuit according to another embodiment of the invention. FIG. 5 is a timing chart showing an amplification operation of the differential amplifier circuit of FIG. 4. In FIG. 4, the same parts as those in FIG. 1 are represented by the same reference numerals, and description thereof will not be repeated.

The differential amplifier circuit of FIG. 4 is different from the differential amplifier circuit of FIG. 1 in that the voltage levels at the gate terminals of the NMOS transistors Mn5 and Mn6 are at the voltage level VDD of the high-potential power source. The destination to which the gate terminal is connected is not necessarily the high-potential power source, and it should suffice that the base-up current flows, so the voltage level at the gate terminal may be a voltage level between the voltage level VDD of the high-potential power source and the voltage level GND of the low-potential power source set in advance.

The circuit constant of each transistor constituting the differential amplifier circuit in FIG. 4 may be the same as the circuit constant of each transistor shown in FIG. 1. Meanwhile, when the voltage level at the destination to which the gate terminal is connected is other than VDD, with regard to the circuit constant of each of the NMOS transistors Mn5 and Mn6, there is the need for measures to correct the base-up current, for example, an increase of W.

As shown in FIG. 5, according to this embodiment, the base-up current does not flow until the amplification initiation signal EN is at H level. At the time t0, if the amplification initiation signal EN is at H level, the NMOS transistors Mn5 and Mn6 are turned on, and drop the voltage levels at the nodes N0 and N1 together with the NMOS transistors Mn0 and Mn1 (differential-pair transistors). Thus, the flip-flop starts the amplification operation, amplifies the differential input signals at high speed, and outputs data according to the differential input signals to the differential outputs.

According to this embodiment, the base-up current flows at the same time the differential-pair transistors are turned on (simultaneously with the amplification operation), so an increase in speed can be achieved while the effects of the first embodiment can be maintained. In addition, even when the voltage level of the input signal is further lowered, the base-up current is added to the current flowing between the differential-pair transistors at the time of the start of amplification, so a differential amplifier circuit with reduced erroneous operation can be realized. Furthermore, the delay DLY and the delay signal END are not required, so a differential amplifier circuit with a smaller layout area can be realized.

### Third Embodiment

Next, yet another embodiment of the invention will be described.

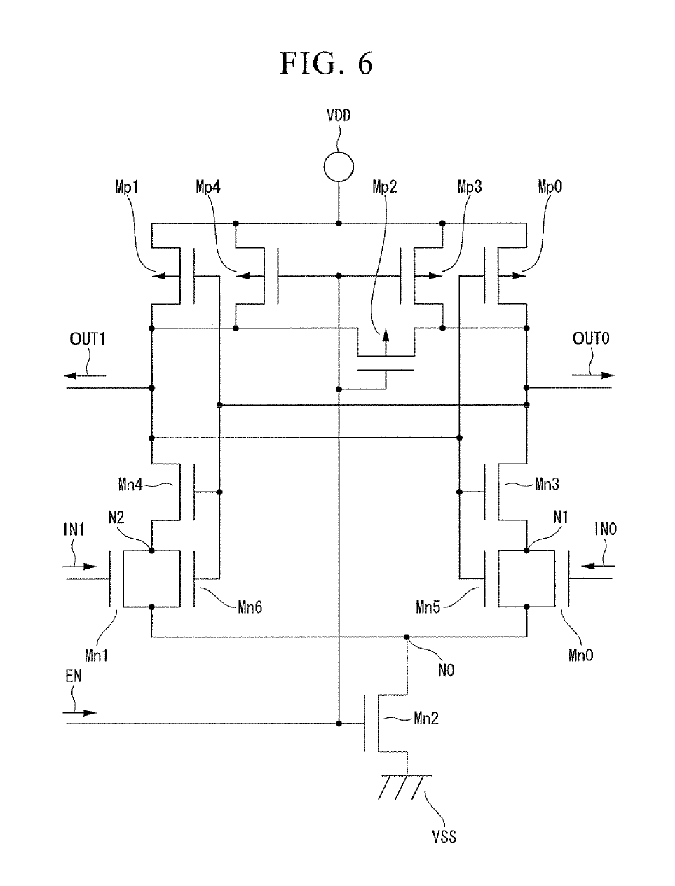

FIG. 6 is a circuit diagram of a differential amplifier circuit according to yet another embodiment of the invention. FIGS. 7A and 7B are timing charts showing amplification operations of the differential amplifier circuit in FIG. 6. In FIG. 6, the same parts as those in FIGS. 1 and 4 are represented by the same reference numerals, and description thereof will not be repeated.

The differential amplifier circuit in FIG. 6 is different from the differential amplifier circuits in FIGS. 1 and 4 in that the connection destination of the gate terminals of the NMOS transistors Mn5 and Mn6 in which the base-up current flows is a holding node of the latch corresponding to data of the differential input signals. That is, the gate terminal of the NMOS transistor Mn5 is connected to a node at which the differential output signal OUT1 is output, and the gate terminal of the NMOS transistor Mn6 is connected to a node at which the differential output signal OUT0 is output.

The circuit constant of each transistor constituting the differential amplifier circuit in FIG. 6 may be the same as the circuit constant of each transistor shown in FIGS. 1 and 4.

According to this embodiment, the base-up current flows at the same time the differential-pair transistors are turned on (simultaneously with the amplification operation), so an increase in speed can be achieved while the effects of the first embodiment can be maintained. In addition, even when the voltage level of the input signal is further lowered, the base-up current is added to the current flowing between the differential-pair transistors at the time of the start of amplification, so a differential amplifier circuit with reduced erroneous operation can be realized. Furthermore, the delay DLY and the delay signal END, or a predetermined power supply voltage is not required, and the configuration can be made by node connection in the differential amplifier circuit, so a differential amplifier circuit with a smaller layout area can be realized.

Although in the differential amplifier circuit according to the embodiment of the invention, a detection section (differential-pair transistors) by the differential input signals is provided on the low-potential power source side, the fundamental technological idea of the invention is not limited thereto. For example, a reverse charge/discharge relationship may be provided, that is, a detection section may be provided on the high-potential power source side. In this case, the voltage level at the time of initial charging of the differential output signals OUT0 and OUT1 by an equalizer (PMOS transistors Mp2 to Mp4) may be the voltage level of the high-potential power source or the voltage level of the low-potential power source, as described above. For example, an equalizer may include NMOS transistors, and may be precharged with the voltage level of the low-potential power source. This can be easily understood by those skilled in the art based on the fundamental technological idea of the invention.

The differential amplifier circuit according to each embodiment of the invention can be applied to semiconductor devices, such as CPU (Central Processing Unit), MPU (Micro Control Unit), DSP (Digital Signal Processor), ASIC (Application Specific Integrated Circuit), and ASSC (Application Specific Standard Circuit).

Examples of the products to which the above-described embodiments can be applied may be, but are not limited to, any semiconductor devices such as SOC (System-On-Chip), MCP (Multi-Chip-Package), and POP (Package-On-Package). Thus, the embodiments of the present invention can be applied to any semiconductor devices in any forms of products and in any forms of package.

The transistors constituting the differential amplifier circuit according to each embodiment of the invention may be field effect transistors (FET). In addition to the MOS (Metal Oxide Semiconductor), various FETs, such as MIS (Metal-Insulator Semiconductor) transistors and TFTs (Thin Film Transistor), may be used. Transistors (for example, bipolar transistors) other than the FETs may be used for a part of the constituent elements of the invention. The NMOS transistor (N-type channel MOS transistor) is a representative of the first conduction-type transistor, and the PMOS transistor (P-type channel MOS transistor) is a representative example of the second conduction-type transistor.

It is apparent that the present invention is not limited to the above embodiments, but may be modified and changed without departing from the scope and spirit of the invention.

What is claimed is:

1. A differential amplifier circuit comprising:
a plurality of differential-pair transistors having gate electrodes that receive differential input signals respectively, different potentials of the differential input signals representing a piece of information;
a plurality of current addition transistors that are connected in parallel to the plurality of differential-pair transistors, respectively;
a latch connected to the plurality of differential-pair transistors, the latch being connected to the plurality of current addition transistors, the latch holding amplified data which have been generated by amplifying the plurality of differential input signals, the latch having a plurality of differential outputs, the plurality of differential outputs being related to the amplified data, the plurality of differential outputs corresponding to the differential input signals respectively; and
a control transistor connected to the plurality of differential-pair transistors, the control transistor connected to the plurality of current addition transistors, the control transistor receiving an activation initiation signal,
wherein the plurality of current addition transistors are transitioned into electrically conductive state either in a period of time from initiation of amplification operation of the differential amplifier circuit by transitioning the control transistor into an electrically conductive state to increasing a differential voltage to cause inversion of one of the plurality of differential outputs of the latch, or at the same time when the amplification operation is initiated.

2. The differential amplifier circuit according to claim 1, wherein each of the gates of the plurality of current addition transistors is coupled to a delayed signal that is generated by delaying the activation initiation signal with a predetermined time, so as to add a predetermined current to respective currents flowing through the plurality of differential-pair transistors.

3. The differential amplifier circuit according to claim 1, wherein each of the gates of the plurality of current addition transistors is coupled to a predetermined voltage, the predetermined voltage is either one of a higher power voltage and a lower power voltage or a potential between the higher power voltage and the lower power voltage.

4. The differential amplifier circuit according to claim 1, wherein the gates of the plurality of current addition transistors are coupled to nodes of the plurality of differential outputs having the same phase as the plurality of differential input signals respectively.

5. The differential amplifier circuit according to claim 1, wherein the plurality of differential-pair transistors and the plurality of current addition transistors are coupled between one of a higher power voltage and a lower power voltage and other of the higher power voltage and the lower power voltage, the other being applied to the latch.

6. The differential amplifier circuit according to claim 1, wherein the latch comprises first and second inverters having gates and outputs which are cross-coupled to each other, the plurality of differential-pair transistors and the plurality of current addition transistors are connected in parallel to each other, each of the plurality of differential-pair transistors is connected in series between a higher power voltage and a lower power voltage, and each of the plurality of current addition transistors is connected between the higher power voltage and the lower power voltage.

7. The differential amplifier circuit according to claim 5, wherein the plurality of differential-pair transistors and the plurality of current addition transistors are connected in parallel to each other, the plurality of differential-pair transistors and the plurality of current addition transistors, the first and second inverters and the control transistor are connected in series between the higher power voltage and the lower power voltage.

8. The differential amplifier circuit according to claim 6, wherein the plurality of differential-pair transistors and the plurality of current addition transistors are connected in parallel to each other, the plurality of differential-pair transistors and the plurality of current addition transistors, the first and second inverters and the control transistor are connected in series between the higher power voltage and the lower power voltage.

9. The differential amplifier circuit according to claim 1, wherein the plurality of differential-pair transistors and the plurality of current addition transistors are field effect transistors of the same conductivity type.

10. The differential amplifier circuit according to claim 8, wherein the control transistor is a field effect transistor of the same conductivity type as the plurality of differential-pair transistors and the plurality of current addition transistors.

11. The differential amplifier circuit according to claim 6, wherein the first inverter is a transistor of a first conductivity type, the second inverter is a transistor of a second conductivity type,
one of the transistors of the first conductivity type and the second conductivity type is the same conductivity type as the plurality of differential-pair transistors and the plurality of current addition transistors.

12. A differential amplifier circuit comprising: a differential input circuit; and a latch,
the differential input circuit comprising:
first and second transistors having gate electrodes that receive differential input signals respectively, different potentials of the differential input signals representing a piece of information;
a control transistor connected in series to the first differential-pair transistor, the control transistor being connected in series to the second differential-pair transistor, the control transistor receiving an activation initiation signal; and
third and fourth transistors being connected in parallel to the first and second transistors,
the latch comprising first and second inverters having gates and outputs which are cross-coupled to each other,
the first and second inverters having a plurality of differential outputs having a differential voltage greater than a differential voltage of the plurality of differential input signals, related to the plurality of differential input signals, the first and second inverters outputting the plurality of differential outputs after operations of the first and second inverters,
the first and second inverters having sources which are connected in series to a plurality of outputs of the differential input circuit, the plurality of outputs of the differential input circuit corresponding to the plurality of differential input signals,
wherein the third and fourth transistors are transitioned into electrically conductive state either in a period of time from initiation of amplification operation of the first and second transistors by transitioning the control transistor into an electrically conductive state to increasing a differential voltage to cause inversion of one of the plurality of differential outputs of the latch, or at the same time when the amplification operation is initiated.

13. The differential amplifier circuit according to claim 12, wherein each of the gates of the third and fourth transistors is coupled to a delayed signal that is generated by delaying the activation initiation signal with a predetermined time, so as to add a predetermined current to respective currents flowing through the first and second transistors.

14. The differential amplifier circuit according to claim 12, wherein each of the gates of the third and fourth transistors is coupled to a predetermined voltage, the predetermined voltage is either one of a higher power voltage and a lower power voltage or a potential between the higher power voltage and the lower power voltage.

15. The differential amplifier circuit according to claim 12, wherein the gates of the third and fourth transistors are coupled to nodes of the plurality of differential outputs having the same phase as the plurality of differential input signals respectively.

16. The differential amplifier circuit according to claim 12, wherein the gates of the third and fourth transistors are connected to nodes of the plurality of differential outputs controlled at a predetermined high potential before the first and second transistors perform amplification operations.

17. The differential amplifier circuit according to claim 12, wherein the first, second, third and fourth transistors are field effect transistors of the same conductivity type.

18. The differential amplifier circuit according to claim 17, wherein the control transistor is a field effect transistor of the same conductivity type as the first, second, third and fourth transistors.

19. The differential amplifier circuit according to claim 17, wherein the first inverter is a transistor of a first conductivity type, the second inverter is a transistor of a second conductivity type,
one of the transistors of the first conductivity type and the second conductivity type is the same conductivity type as the first, second, third and fourth transistors.

20. The differential amplifier circuit according to claim 18, wherein the first inverter is a transistor of a first conductivity type, the second inverter is a transistor of a second conductivity type,
one of the transistors of the first conductivity type and the second conductivity type is the same conductivity type as the first, second, third and fourth transistors.
